(19) United States
(12) Patent Application Publication
(10) Pub. No.: US 2015/0263037 A1
(43) Pub. Date: Sep. 17, 2015

(54) INTEGRATED CIRCUIT DEVICE AND METHOD FOR MANUFACTURING THE SAME

(71) Applicant: Kabushiki Kaisha Toshiba, Minato-ku (JP)

(72) Inventor: Kotaro NODA, Yokkaichi (JP)

(73) Assignee: Kabushiki Kaisha Toshiba, Minato-ku (JP)

(21) Appl. No.: 14/644,714

(22) Filed: Mar. 11, 2015

(30) Foreign Application Priority Data
Mar. 17, 2014 (JP) 2014-054155

(51) Int. Cl. H01L 27/115; H01L 21/3205; H01L 21/311

(52) U.S. Cl. CPC H01L 27/11582; H01L 21/31111; H01L 21/31144; H01L 21/3205

(57) ABSTRACT

An integrated circuit device according to one embodiment includes a body film, a stopper film, a stacked structure body, a first vertical member and a second vertical member. The stopper film is selectively provided in the body film. A part of an upper surface of the stopper film is covered by the body film. The stacked structure body is provided on the body film. The first vertical member is provided in the body film and the stacked structure body. The first vertical member extends in a stacked direction of the stacked structure body. A lower end of the first vertical member is in the stopper film. A second vertical member is provided in the body film and the stacked structure body. The second vertical member extends in the stacked direction. The second vertical member is located side of the stopper film.

### CROSS-REFERENCE TO RELATED APPLICATIONS

This application is based upon and claims the benefit of priority from Japanese Patent Application No. 2014-054155, filed on Mar. 17, 2014; the entire contents of which are incorporated herein by reference.

### FIELD

Embodiments described herein relate to an integrated circuit device and a method for manufacturing the same.

### BACKGROUND

In recent years, there has been proposed a stacked memory device in which insulating films and electrode films are alternately stacked to form a stacked body, through-holes are formed in the stacked body, memory films capable of storing charges are formed on the inner surfaces of the through-holes, and silicon pillars are formed in the through-holes, whereby memory cells are formed between the silicon pillars and the electrode films. In such a stacked memory device, slits are formed in the stacked body to divide the electrode films into a plurality of portions and improve controllability of the memory cells.

### BRIEF DESCRIPTION OF THE DRAWINGS

FIG. 1 is a sectional view illustrating an integrated circuit device according to a first embodiment;

FIG. 2A to FIG. 10 are sectional views illustrating a method for manufacturing the integrated circuit device according to the first embodiment; and

FIG. 11A to FIG. 11C are sectional views illustrating a method for manufacturing an integrated circuit device according to a second embodiment.

### DETAILED DESCRIPTION

An integrated circuit device according to one embodiment includes a body film, a stopper film, a stacked structure body, a first vertical member and a second vertical member. The stopper film is selectively provided in the body film. A part of an upper surface of the stopper film is covered by the body film. The stacked structure body is provided on the body film. The first vertical member is provided in the body film and the stacked structure body. The first vertical member extends in a stacked direction of the stacked structure body. A lower end of the first vertical member is in the stopper film. A second vertical member is provided in the body film and the stacked structure body. The second vertical member extends in the stacked direction. The second vertical member is located side of the stopper film.

A method for manufacturing an integrated circuit device according to one embodiment, includes selectively forming a stopper film on a first body film and forming a second body film that covers a part of an upper surface of the stopper film and exposes a remaining part. The method includes forming a stacked structure body on the second body film. The method includes etching the stacked structure body to form a first hole that reaches the remaining part of the stopper film. The method includes forming a first vertical member in the first hole. The method includes etching the stacked structure body, the second body film, and the first body film to form a second hole that passes a side of the stopper film. The method includes forming a second vertical member in the second hole.

### First Embodiment

Embodiments of the invention are described below with reference to the drawings.

First, a first embodiment is described.

An integrated circuit device according to the embodiment is a nonvolatile semiconductor memory device of a stacked type.

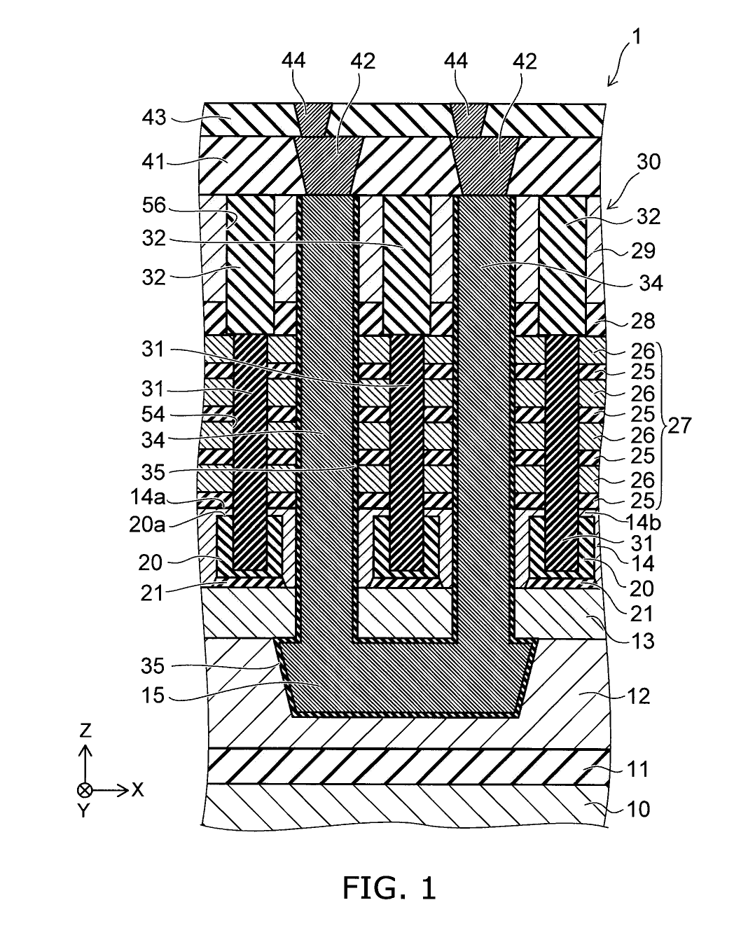

FIG. 1 is a sectional view illustrating the integrated circuit device according to the embodiment.

As shown in FIG. 1, in an integrated circuit device 1 according to the embodiment, a silicon substrate 10 is provided. A silicon oxide film 11 and polysilicon films 12, 13, and 14 are stacked on the silicon substrate 10 in this order. The polysilicon films 12, 13, and 14 are formed of polysilicon doped with boron (B). A back gate electrode as a body film is formed of the polysilicon films 12, 13, and 14. Note that a peripheral circuit may be formed between the silicon substrate 10 and the silicon oxide film 11. A pipe connector 15 made of, for example, polysilicon is provided in an upper layer portion of the polysilicon film 12.

In the following description, in the specification, an XYZ orthogonal coordinate system is adopted for convenience of description. Two directions parallel to the upper surface of the silicon substrate 10 and orthogonal to each other are referred to as “X-direction” and “Y-direction”. A direction perpendicular to the upper surface of the silicon substrate 10 is referred to as “Z-direction”. The shape of the pipe connector 15 is a substantially parallelepiped shape, the longitudinal direction of which is the X-direction.

In the polysilicon film 14, a plurality of stopper films 20 are selectively provided. The plurality of stopper films 20 are disposed to be spaced from one another in the X-direction. The stopper films 20 linearly extend along the Y-direction. The stopper films 20 are embedded in the polysilicon film 14. Upper surfaces 20a of the stopper films 20 are present in positions lower than an upper surface 14a of the polysilicon film 14. Therefore, a part of an upper layer portion 14b of the polysilicon film 14 is disposed on both end parts in the X-direction of the upper surfaces 20a of the stopper films 20 and covers the X-direction both end portions. On the other hand, the polysilicon film 14 does not cover X-direction center portions on the upper surfaces 20a of the stopper films 20.

The stopper films 20 are formed of, for example, metal, a metal oxide, or a metal nitride. The stopper films 20 are formed of, for example, one or more kinds of metal selected from the group consisted of titanium (Ti), aluminum (Al), tantalum (Ta), tungsten (W), molybdenum (Mo), manganese (Mn), and zirconium (Zr), or oxides or nitrides of the one or more kinds of metal. The stopper films 20 are formed of, for example, a tantalum oxide (TaO).

Interface layers 21 are provided between the lower surfaces of the stopper films 20 and the polysilicon film 13. The interface layers 21 are in contact with the polysilicon film 13 and the stopper films 20. The composition of the interface layers 21 is different from the composition of the polysilicon film 13 and the composition of the stopper films 20. The interface layers 21 are formed of, for example, metal or silicon, or oxide or nitride of the metal or the silicon. The interface layers 21 are formed of, for example, one or more kinds of materials selected from the group consisted of silicon (Si), titanium (Ti), aluminum (Al), tantalum (Ta), tungsten (W), molybdenum (Mo), manganese (Mn), and zirconium (Zr), or oxides or nitrides of the materials. The interface layers 21 are formed of, for example, a silicon oxide (SiO₂).

A stacked body 27 in which inter-electrode insulating films 25 and control gate electrode films 26 are alternately stacked is provided on the polysilicon film 14. The inter-electrode insulating films 25 are made of, for example, non-doped polysilicon or silicon oxide. The control gate electrode films 26 are made of, for example, polysilicon containing boron. In an example shown in FIG. 1, the numbers of the stacked inter-electrode insulating films 25 and the stacked control gate electrode films 26 are four, respectively. However, the numbers of the stacked inter-electrode insulating films 25 and the stacked control gate electrode films 26 are not limited to this. On the stacked body 27, an inter-electrode insulating film 28 and a selection gate electrode film 29 are stacked in this order. A stacked structure body 30 is formed of the stacked body 27, the inter-electrode insulating film 28, and the selection gate electrode film 29. The compositions of the inter-electrode insulating films 25, the control gate electrode films 26, the inter-electrode insulating film 28, and the selection gate electrode film 29 are different from the composition of the stopper films 20.

In the polysilicon film 14 and the stacked body 27, tabular insulating members 31 extending in the Y-direction and the Z-direction are provided. The lower ends of the insulating members 31 are located in the X-direction center portions of the stopper films 20. In the inter-electrode insulating film 28 and the selection gate electrode film 29, tabular insulating members 32 extending in the Y-direction and the Z-direction are provided. The insulating members 32 are disposed in regions directly above the insulating members 31 and are in contact with the insulating members 31. The insulating members 31 and 32 are formed of an insulating material such as a silicon oxide, for example. The insulating members 31 and 32 form first vertical members provided in the stacked structure body 30 and the polysilicon film 14, extending in the stacked direction (the Z-direction), and having lower ends that are located in the stopper films 20.

A plurality of silicon pillars 34 extending in the Z-direction to pierce through the polysilicon films 13 and 14, the stacked body 27, the inter-electrode insulating film 28, and the selection gate electrode film 29. The shape of the silicon pillars 34 is a substantially columnar shape reduced in diameter downward. The silicon pillars 34 pass among the stopper films 20 without coming into contact with the stopper films 20. The lower ends of the silicon pillars 34 are in contact with X-direction both end portions of the pipe connector 15. The silicon pillars 34 are second vertical members provided in the stacked structure body 30, the polysilicon film 14, and the polysilicon film 13, extending in the stacked direction (the Z-direction), and passing sides of the stopper films 20. A part of each of the silicon pillars 34 is located on side of the stopper films 20.

A structure body consisting of one pipe connector 15 and two silicon pillars 34 coupled to the pipe connector 15 is integrally formed of polysilicon. A memory film 35 is provided on the surface of the structure body. The memory film 35 is a film that can exchange charges with the silicon pillars 34 and store the charges.

For example, in the memory film 35, a tunnel insulating layer, a charge storage layer, and a block insulating layer are stacked in this order from the side of the pipe connector 15 and the silicon pillars 34. The tunnel insulating layer is a layer that is usually insulative but allows a tunnel current to flow when a predetermined voltage within a range of a driving voltage of the integrated circuit device 1 is applied to the layer. The charge storage layer is a layer having an ability to store charges and is, for example, a layer including a trap site for electrons. The block insulating layer is a layer that does not substantially allow an electric current to flow even if a voltage is applied to the layer within the range of the driving voltage of the integrated circuit device 1. For example, the tunnel insulating layer and the block insulating layer are formed of a silicon oxide. The charge storage layer is formed of a silicon nitride.

An interlayer insulating film 41 is provided on the stacked structure body 30. Plugs 42 connected to the silicon pillars 34 are provided in the interlayer insulating film 41. An interlayer insulating film 43 is provided on the interlayer insulating film 41. Plugs 44 connected to the plugs 42 are provided in the interlayer insulating film 43.

A method for manufacturing the integrated circuit device according to the embodiment is described.

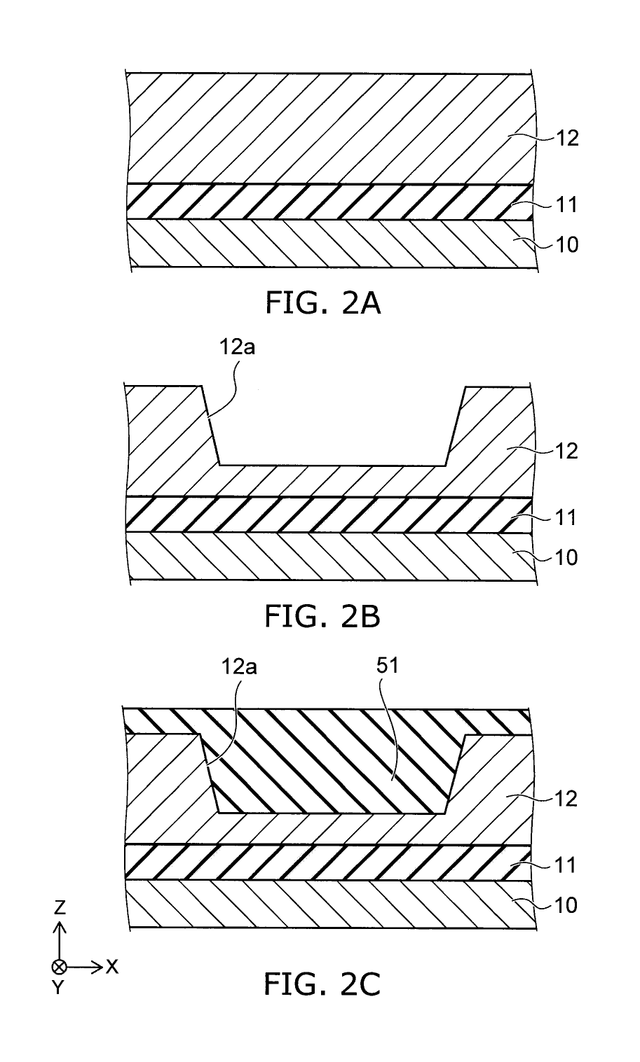

FIG. 2A to FIG. 10 are sectional views illustrating the method for manufacturing the integrated circuit device according to the embodiment.

First, as shown in FIG. 2A, the silicon oxide film 11 is formed on the silicon substrate 10. The polysilicon film 12 is formed on the silicon oxide film 11. Note that a peripheral circuit may be formed between the silicon substrate 10 and the silicon oxide film 11.

Subsequently, as shown in FIG. 2B, a concave portion 12a, the longitudinal direction of which is the X-direction, is formed on the upper surface of the polysilicon film 12.

Subsequently, as shown in FIG. 2C, a sacrificial material 51, for example, a silicon nitride is deposited on the polysilicon film 12. The sacrificial material 51 is also embedded in the concave portion 12a.

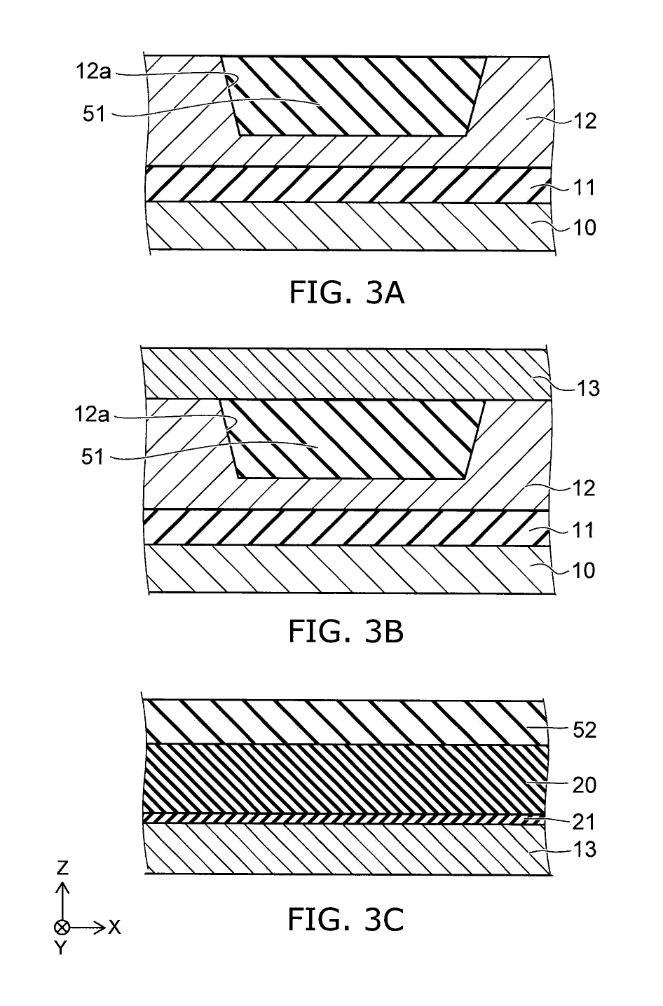

Subsequently, as shown in FIG. 3A, CMP (Chemical Mechanical Polishing) is applied to the upper surface of the sacrificial material 51 to remove a portion of the sacrificial material 51 deposited on the outside of the concave portion 12a.

Subsequently, as shown in FIG. 3B, the polysilicon film 13 is formed on the polysilicon film 12 and the sacrificial material 51.

Subsequently, as shown in FIG. 3C, the interface layer 21 is formed on the polysilicon film 13. The interface layer 21 is formed of, for example, metal or silicon, or oxide or nitride of the metal or the silicon. The interface layer 21 is formed of, for example, a silicon oxide (SiO₂). Note that the interface layer 21 may be formed of silicon (Si) or a silicon nitride (SiN).

Subsequently, the stopper film 20 is formed. The composition of the stopper film 20 is made different from the composition of the interface layer 21. The stopper film 20 is formed of, for example, metal, a metal oxide, or a metal nitride. The stopper film 20 is formed of, for example, a tantalum oxide (TaO). The interface layer 21 and the stopper film 20 are formed by, for example, an LP-CVD (Low Pressure Chemical Vapor Deposition) method, a PE-CVD (Plasma Enhanced CVD) method, a PVD (Physical Vapor Deposition) method, or an ALD (Atomic Layer Deposition) method. Subsequently, a hard mask 52 is formed on the stopper film 20. Note that, in FIG. 3C to FIG. 7, for simplification, illustration of structure below the polysilicon film 13 is omitted.

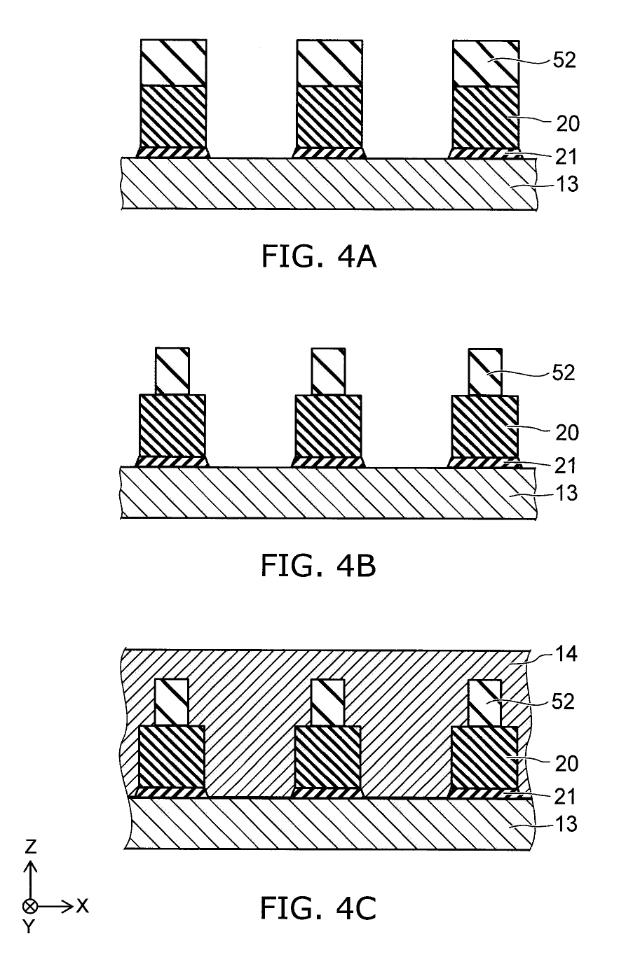

Subsequently, as shown in FIG. 4A, the hard mask 52 is processed into a line-and-space shape extending in the Y-direction by a lithography method. Subsequently, anisotropic etching such as RIE (Reactive Ion Etching) is applied to the stopper film 20 and the interface layer 21 using the hard masks 52 as masks. Consequently, the stopper film 20 and the interface layer 21 are selectively removed and processed into the line-and-space shape extending in the Y-direction.

Subsequently, as shown in FIG. 4B, the hard masks 52 are slimmed to reduce the width of the hard masks 52 by performing, for example, wet etching.

Subsequently, as shown in FIG. 4C, polysilicon doped with boron (B) is deposited over the entire surface to cover the stopper films 20 and the hard masks 52 to form the polysilicon film 14.

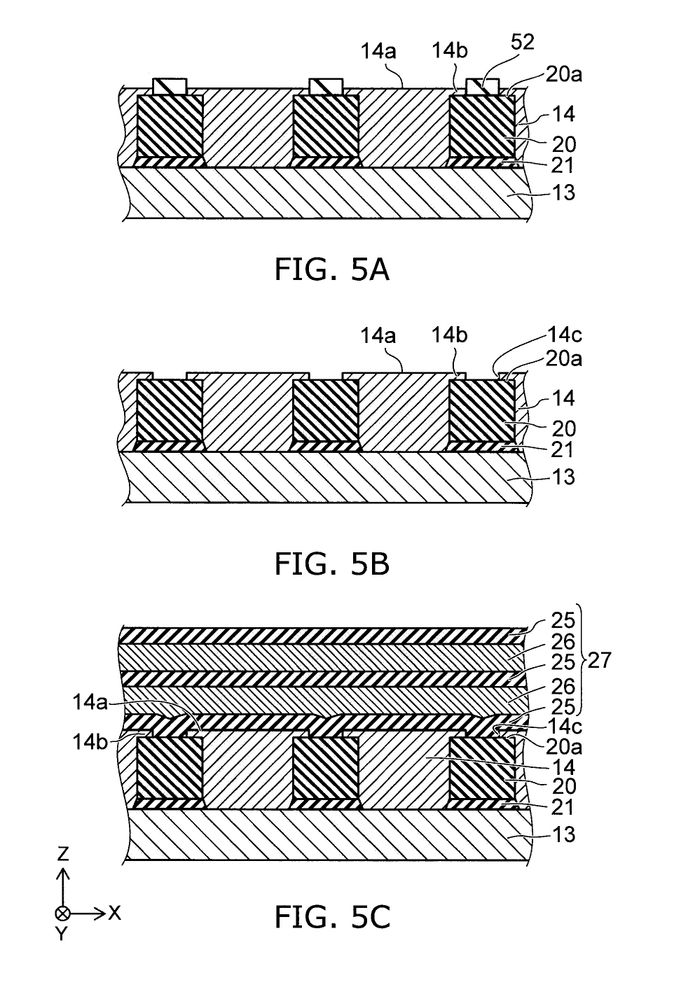

Subsequently, as shown in FIG. 5A, the upper surface 14a of the polysilicon film 14 is planarized by performing the CMP or etch-back of the entire surface. In this case, the upper end portions of the hard masks 52 are exposed from the upper surface 14a of the polysilicon film 14. However, the upper surfaces 20a of the stopper films 20 are not exposed. That is, while a state in which the upper surface 14a of the polysilicon film 14 is located above the upper surfaces 20a of the stopper films 20 is maintained, planarization treatment is applied to the upper surface 14a of the polysilicon film 14. Consequently, a part of the upper layer portion 14b of the polysilicon film 14 remains on X-direction both end portions of the upper surfaces 20a of the stopper films 20.

Subsequently, as shown in FIG. 5B, for example, the wet etching is applied to the hard masks 52 to remove the hard masks 52. Consequently, concave portions 14c are formed in the upper layer portion 14b of the polysilicon film 14. The shape of the concave portions 14c is a linear shape extending in the Y-direction. The upper surfaces 20a of the stopper films 20 are exposed on the bottom surfaces of the concave portions 14c. As a result, the polysilicon film 14 covers the X-direction both end portions on the upper surfaces 20a of the stopper films 20 and exposes X-direction center portions on the upper surfaces 20a of the stopper films 20.

Subsequently, as shown in FIG. 5C, the inter-electrode insulating films 25 made of, for example, non-doped polysilicon or silicon oxide and the control gate electrode films 26 made of, for example, polysilicon doped with boron are alternately stacked to form the stacked body 27. In this case, a part of the inter-electrode insulating film 25 in the bottom of the stacked body 27 enters the insides of the concave portions 14c of the polysilicon film 14 and comes into contact with the upper surfaces 20a of the stopper films 20.

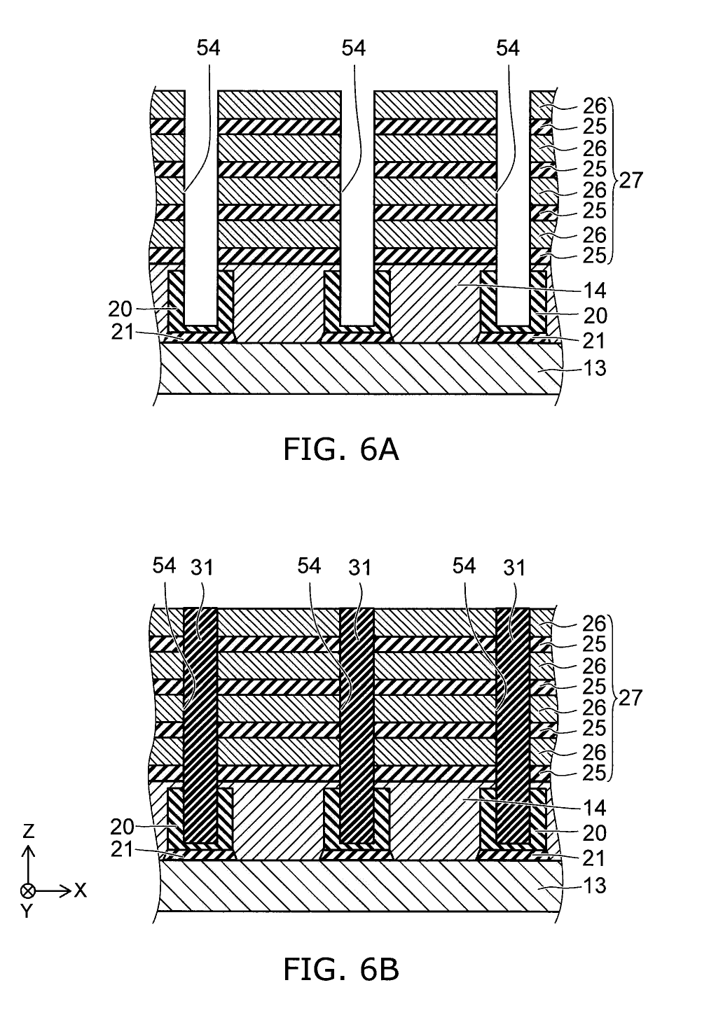

Subsequently, as shown in FIG. 6A, the stacked body 27 is selectively removed using lithography and dry etching, whereby slits 54 extending in the Y-direction and the Z-direction are formed in regions directly above the stopper films 20. In this case, since the concave portions 14c of the polysilicon film 14 are formed in regions directly below the slits 54, the slits 54 are allowed to communicate with the concave portions 14c. Therefore, it is hardly necessary to etch the polysilicon film 14. Since the etching is stopped in the stopper films 20, the lower ends of the slits 54 enter the inside of the stopper films 20 but do not pierce through the stopper films 20.

Subsequently, as shown in FIG. 6B, an insulating material is deposited over the entire surface and the upper surface of the insulating material is planarized, whereby the insulating members 31 are embedded in the slits 54.

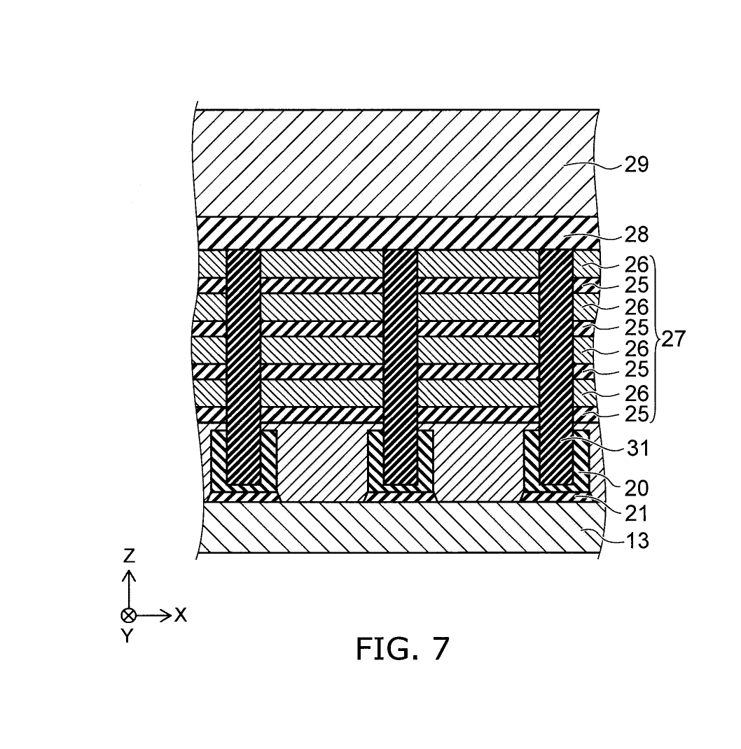

Subsequently, as shown in FIG. 7, the inter-electrode insulating film 28 made of, for example, a silicon oxide and the selection gate electrode film 29 made of, for example, polysilicon are formed. In this way, the compositions of the inter-electrode insulating films 25, the control gate electrode films 26, the inter-electrode insulating film 28, and the selection gate electrode film 29 that cover the stopper films 20 are made different from the composition of the stopper films 20.

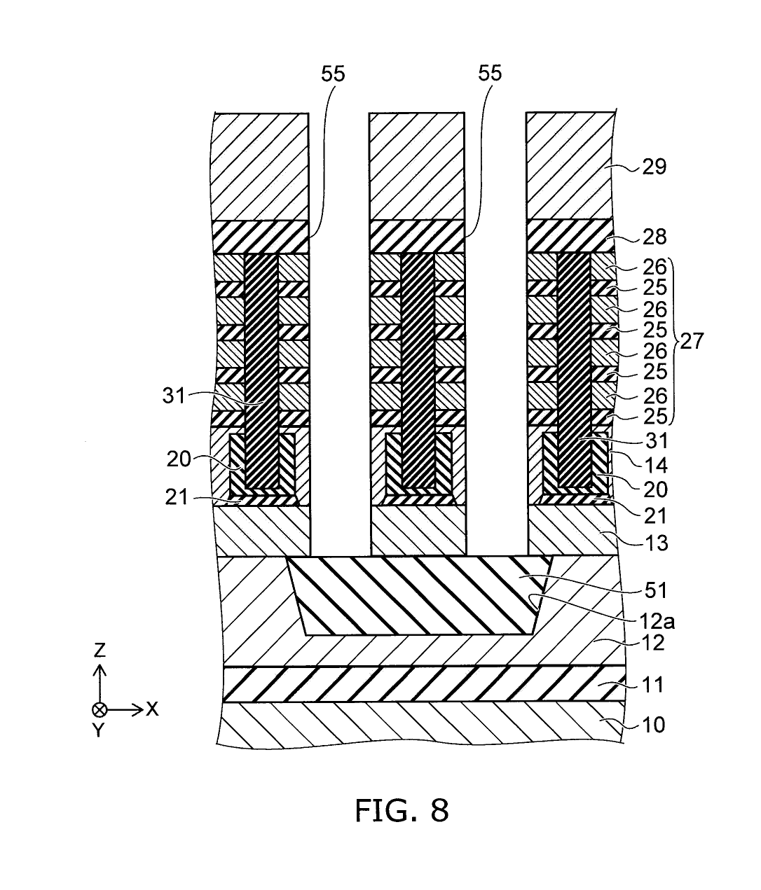

Subsequently, as shown in FIG. 8, memory holes 55 extending in the Z-direction piercing through the selection gate electrode film 29, the inter-electrode insulating film 28, the stacked body 27, and the polysilicon films 14 and 13 are formed by the lithography and the etching to pass regions among the stopper films 20 and reach X-direction both end portions of the concave portion 12a of the polysilicon film 12. The memory holes 55 are caused to communicate with the concave portion 12a. In this case, the memory holes 55 are formed to pass the sides of the stopper films 20 and are prevented from coming into contact with the stopper films 20.

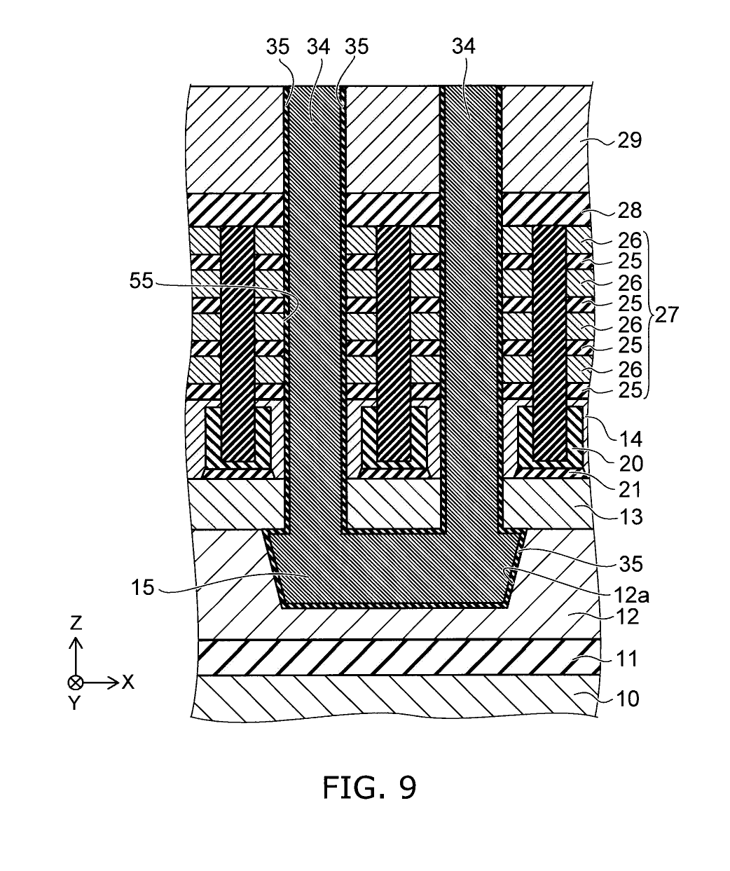

Subsequently, as shown in FIG. 9, the wet etching is performed via the memory holes 55 to remove the sacrificial material 51 from the inside of the concave portion 12a. Subsequently, a block insulating layer, a charge storage layer, and a tunnel insulating layer are formed in this order on the inner surface of a hollow consisting of the concave portion 12a and the memory holes 55 to form the memory film 35. Subsequently, polysilicon is embedded in the hollow consisting of the concave portion 12a and the memory holes 55. Consequently, the pipe connector 15 is formed in the concave portion 12a. Also, the silicon pillars 34 are formed in the memory holes 55.

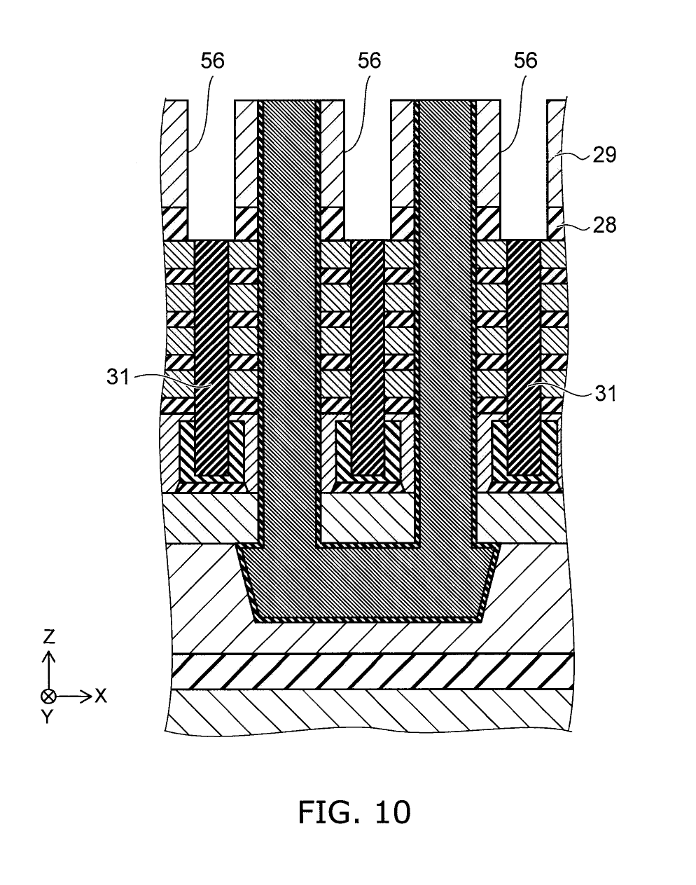

Subsequently, as shown in FIG. 10, the selection gate electrode film 29 and the inter-electrode insulating film 28 are selectively removed by the lithography and the etching to form slits 56 in regions directly above the insulating members 31.

Subsequently, as shown in FIG. 1, an insulating material such as a silicon oxide for example is deposited and planarization treatment is applied to the insulating material, whereby the insulating members 32 are embedded in the slits 56.

Subsequently, the interlayer insulating film 41 is formed. Holes are formed in the interlayer insulating film 41. A metal material is deposited in the holes and the CMP is applied to the metal material, whereby the plugs 42 are formed in the interlayer insulating film 41. Subsequently, the interlayer insulating film 43 is formed. Holes are formed in the interlayer insulating film 43. A metal material is deposited in the holes and the CMP is applied to the metal material, whereby the plugs 44 are formed in the interlayer insulating film 43. In this way, the integrated circuit device 1 according to the embodiment is manufactured.

Effects of the embodiment are described.

In the embodiment, in the process shown in FIG. 5A, when the planarization treatment is applied to the upper surface 14a of the polysilicon film 14, the planarization treatment is stopped while a state in which the upper surface 14a of the polysilicon film 14 is located above the upper surfaces 20a of the stopper films 20 is maintained. Therefore, in the process shown in FIG. 5B, even after the hard masks 52 are removed, the upper layer portion 14b of the polysilicon film 14 remains in a claw shape on the X-direction both end portions on the upper surfaces 20a of the stopper films 20. As a result, in the manufacturing process for the integrated circuit device 1, the stopper films 20 less easily fall off from the polysilicon film 14. The integrated circuit device 1 is easily manufactured.

On the other hand, if the entire stopper films 20 are exposed on the upper surface of the polysilicon film 14 in the processes shown in FIG. 5A and FIG. 5B, it is likely that the stopper films 20 lift off and fall off from the polysilicon film 14.

According to the embodiment, the interface layers 21 are provided between the polysilicon film 13 and the stopper films 20. Consequently, adhesion between the polysilicon film 13 and the stopper films 20 is improved. The stopper films 20 less easily fall off from the polysilicon film 14.

Note that at least one of the interface layers 21 and the stopper films 20 may be formed of a conductive material such as metal. Consequently, it is possible to reduce the resistance of a back gate electrode consisting of the polysilicon films 12 to 14.

The interface layers 21 may be formed by a chemical reaction of a body film and the stopper films 20. For example, it is also possible that an oxygen-containing film (not shown in the figure) made of a material including oxygen, for example, a silicon oxide is formed on the polysilicon film 13 and the stopper films 20 are formed of metal and oxidized by the oxygen-containing film. Consequently, metal oxide layers made of oxide of the metal forming the stopper films 20 are formed as the interface layers 21.

Alternatively, it is also possible that the stopper films 20 are formed of metal and a siliciding reaction is caused between the polysilicon film 13 and the stopper films 20. Consequently, silicide layers made of silicide of the metal forming the stopper films 20 are formed as the interface layers 21.

Further, when the adhesion between the polysilicon film 13 and the stopper films 20 is satisfactory to a degree causing no problem in practical use, the interface layers 21 do not have to be formed. Furthermore, the order of the process for forming the slits 54 shown in FIG. 6A and the process for forming the memory holes 55 shown in FIG. 8 may be opposite.

### Second Embodiment

A second embodiment is described.

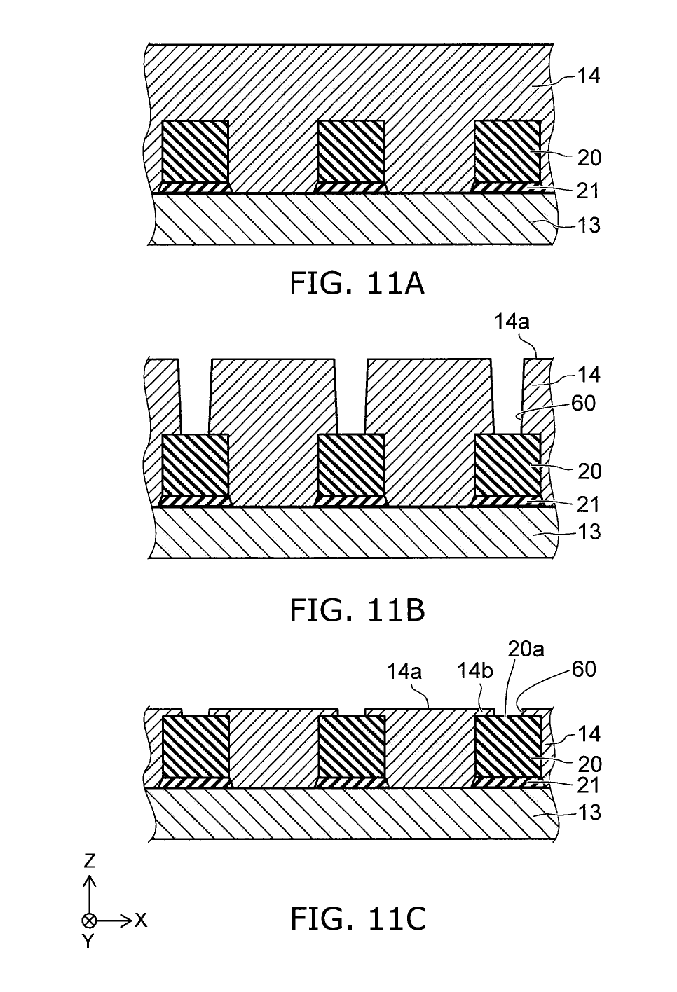

FIGS. 11A to 11C are sectional views illustrating a method for manufacturing an integrated circuit device according to the embodiment.

First, the processes shown in FIG. 2A to FIG. 4A are carried out. That is, the silicon oxide film 11 and the polysilicon films 12 and 13 are formed on the silicon substrate 10. The interface layer 21 and the stopper film 20 are formed on the polysilicon film 13. The interface layer 21 and the stopper film 20 are processed into a line-and-space shape using the hard masks 52.

Subsequently, as shown in FIG. 11A, the hard masks 52 are removed. Subsequently, the polysilicon film 14 is formed to cover the processed interface layers 21 and stopper films 20.

Subsequently, as shown in FIG. 11B, linear slits 60 extending in the Y-direction are formed in regions directly above the X-direction center portions of the stopper films 20 in the polysilicon film 14 by the lithography. The upper surfaces 20a of the stopper films 20 are exposed on the bottom surfaces of the slits 60.

Subsequently, as shown in FIG. 11C, planarization treatment is applied to the upper surface 14a of the polysilicon film 14. The planarization treatment is stopped in a state in which the upper surface 14a of the polysilicon film 14 is located above the upper surfaces 20a of the stopper films 20. Consequently, a part of the upper layer portion 14b of the polysilicon film 14 remains on the upper surfaces 20a of the stopper films 20.

The following processes are the same as the processes in the first embodiment. That is, the processes shown in FIG. 5C to FIG. 10 are carried out.

In the embodiment, as in the first embodiment, a part of the upper layer portion 14b of the polysilicon film 14 is left on the upper surfaces 20a of the stopper films 20. Consequently, it is possible to prevent the stopper films 20 from falling off from the polysilicon film 14. Components, manufacturing methods, and effects other than those described above in the embodiment are the same as those in the first embodiment.

Note that, in the examples described in the embodiments, the structure body consisting of the stopper film 20, the insulating member 31, and the insulating member 32 is provided in each of regions among the silicon pillars 34 in the X-direction. However, the structure body does not always have to be provided in all the regions among the silicon pillars 34. That is, the structure body consisting of the stopper film 20, the insulting member 31, and the insulating member 32 may be arbitrarily disposed.

According to the embodiments described above, it is possible to realize an integrated circuit device that is easily manufactured and a method for manufacturing the integrated circuit device.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. An integrated circuit device comprising:
a body film;
a stopper film selectively provided in the body film, a part of an upper surface of the stopper film being covered by the body film,
a stacked structure body provided on the body film;
a first vertical member provided in the body film and the stacked structure body, the first vertical member extending in a stacked direction of the stacked structure body, a lower end of the first vertical member being in the stopper film; and
a second vertical member provided in the body film and the stacked structure body, the second vertical member extending in the stacked direction, and being located on side of the stopper film.

2. The device according to claim 1, further comprising a memory film provided on a surface of the second vertical member, wherein
the stacked structure body includes a plurality of electrode films and a plurality of insulating films, each of the plurality of electrode films and each of the plurality of insulating films alternately stacked,
the first vertical member is made of an insulating material,
the second vertical member is made of a semiconductor material, and
composition of the stopper film is different from composition of the insulating films and composition of the electrode films.

3. The device according to claim 1, wherein the stopper film is formed of one or more kinds of metal selected from the group consisted of titanium, aluminum, tantalum, tungsten, molybdenum, manganese, and zirconium, or oxides or nitrides of the one or more kinds of metal.

4. The device according to claim 1, further comprising an interface layer provided between a lower surface of the stopper film and the body film, the interface layer having composition different from composition of the stopper film.

5. The device according to claim 1, wherein a portion disposed on the side of the stopper film in the body film is made of a conductive material.

6. The device according to claim 1, wherein
a shape of the stopper film is a linear shape extending in a first direction orthogonal to the stacked direction,
a shape of the first vertical member is a tabular shape extending in the stacked direction and the first direction, and
a shape of the second vertical member is a columnar shape.

7. The device according to claim 2, further comprising:
a third vertical member provided in the body film and the stacked structure body, the third vertical member extending in the stacked direction, being located on side of the stopper film, and being made of a semiconductor material;
a memory film provided on a surface of the third vertical member; and
a connecting member connected between a lower end of the second vertical member and a lower end of the third vertical member.

8. The device according to claim 2, wherein the first vertical member is located between the second vertical member and the third vertical member.

9. The device according to claim 8, further comprising an insulation film provided on a surface of the connecting member, wherein
the insulation film is jointed the memory film provided on the surface of the second vertical member and the memory film provided on the surface of the third vertical member,
the body film is made of a conductive material, and
the connecting member is located in the body film.

10. The device according to claim 7, wherein the second vertical member, the third vertical member and the connecting member are monolithically formed.

11. A method for manufacturing an integrated circuit device comprising:
selectively forming a stopper film on a first body film and forming a second body film that covers a part of an upper surface of the stopper film and exposes a remaining part;
forming a stacked structure body on the second body film;
etching the stacked structure body to form a first hole that reaches the remaining part of the stopper film;
forming a first vertical member in the first hole;
etching the stacked structure body, the second body film, and the first body film to form a second hole that passes a side of the stopper film; and
forming a second vertical member in the second hole.

12. The method according to claim 11, wherein
the forming the second body film includes:
forming the stopper film over an entire surface of the first body film;
forming a mask member on the stopper film;
etching the stopper film using the mask member as a mask;
reducing width of the mask member;
forming the second body film to cover the stopper film and the mask member reduced in the width; and
removing the mask member.

13. The method according to claim 11, wherein
the forming the second body film includes:
forming the second body film to cover the entire stopper film; and
forming a third hole in the second body film, the third hole reaching the stopper film.

14. The method according to claim 11, wherein the stopper film is formed of one or more kinds of metal selected from the group consisted of titanium, aluminum, tantalum, tungsten, molybdenum, manganese, and zirconium, or oxides or nitrides of the one or more kinds of metal.

15. The method according to claim 11, further comprising forming a memory film on an inner surface of the second hole, wherein
the forming the stacked structure body includes alternately stacking electrode films and insulating films,
the first vertical member is formed of an insulating material, and
the second vertical member is formed of a semiconductor material.
